(19) United States
(12) Patent Application Publication
(10) Pub. No.: US 2011/0211322 A1
(43) Pub. Date: Sep. 1, 2011

(54) ELECTRONIC DEVICE

(75) Inventor: Ted Ju, Keelung (TW)

(73) Assignee: LOTES CO., LTD., Keelung City (TW)

(21) Appl. No.: 12/895,162

(22) Filed: Sep. 30, 2010

(30) Foreign Application Priority Data
Mar. 1, 2010 (CN) 201020122567.3

(51) Int. Cl. H05K 7/00

(52) U.S. Cl. 361/783

(57) ABSTRACT

An electronic device includes a printed circuit board, conductive portions coated with a solder paste, a chip module installed on the printed circuit board, contact portions formed at the bottom of the chip module and corresponding to the conductive portions respectively, and at least one support portion formed between the chip module and the printed circuit board and having an end coupled to the printed circuit board and another end coupled to the contact portion of the chip module. When the chip module and printed circuit board are deformed in a high-temperature process, the contact portions will still be in contact with the solder paste. Since the printed circuit board is warped upward at the middle and downward at the periphery in a soldering process, the support portion maintains a specific distance between the two to prevent excessive melted solder pastes from flowing towards the periphery or causing short circuits.

### CROSS-REFERENCE TO RELATED PATENT APPLICATION

This non-provisional application claims benefits and priority under 35 U.S.C. §119(a) on Patent Application No. 201020122567.3 filed in The People's Republic of China on Mar. 1, 2010, which is incorporated herein by reference in its entirety.

Some references, if any, which may include patents, patent applications and various publications, are cited in a reference list and discussed in the description of this invention. The citation and/or discussion of such references is provided merely to clarify the description of the present invention and is not an admission that any such reference is “prior art” to the invention described herein. All references, if any, listed, cited and/or discussed in this specification are incorporated herein by reference in their entireties and to the same extent as if each reference was individually incorporated by reference.

### BACKGROUND OF THE INVENTION

1. Field of the Invention

The present invention relates to an electronic device, and more particularly to an electronic device capable of preventing a short circuit.

2. Description of the Related Art

With reference to FIG. 1 for a conventional electronic device, the electronic device comprises an electronic component 1 and a printed circuit board 2. The electronic component 1 and the printed circuit board 2 are fixed and electrically connected by a soldering process. The electronic component 1 comprises a main body 11 and a plurality of contact portions 12 formed at the bottom of the main body 11. The printed circuit board 2 includes a plurality of conductive pads 21 installed at positions corresponding to the contact portions 12 respectively.

When the electronic component 1 is soldered onto the printed circuit board 2, the conductive pads 21 on the printed circuit board 2 are coated with a layer of solder paste 3 first, and then the electronic component 1 is installed at a corresponding position of the printed circuit board 2, such that the contact portions 12 are positioned at the top of the conductive pads 21, and then the printed circuit board 2 and the electronic component 1 are placed and heated in a furnace (not shown in the figure), such that the contact portions 12 and the conductive pads 21 are positioned and electrically connected after the solder paste 3 is melted, and a good electric connection between the electronic component 1 and the printed circuit board 2 can be achieved.

Although the electronic component of the aforementioned electronic device can be soldered onto the printed circuit board, the following drawbacks still exist.

1. The bottom of the main body and the printed circuit board come with a flat and uniform design, so that the contact portions and the corresponding conductive pads are kept equidistantly. When the printed circuit board is soldered in the furnace, the high-temperature soldering process will warp the printed circuit board upward at the middle and downward at the periphery. As a result, the contact portions proximate to the middle of the main body may be pushed by the solder paste on the printed circuit board easily. The interaction of forces drives the melted solder paste to flow and disperse towards the periphery during the soldering process, such that adjacent solder pastes may cause a short circuit, and result in an electric disconnection between the electronic component and the printed circuit board.

2. Since the printed circuit board may warp upward at the middle and downward at the periphery during the soldering process, the contact portions proximate to the middle of the main body has a greater distance from the corresponding conductive pads on the printed circuit board, compared with the original distance between the contact portions and the corresponding conductive pads. As a result, a poor soldering problem such as empty soldering and open soldering may occur between some of the solder balls and the printed circuit board and further affect the operation and performance of the electronic component.

Therefore, a heretofore unaddressed need exists in the art to address the aforementioned deficiencies and inadequacies.

### SUMMARY OF THE INVENTION

In one aspect, the present invention provides an electronic device that can prevent a short circuit by means of the support method.

In one embodiment, the present invention adopts the following inventive measures and provides an electronic device comprising: a printed circuit board, having a plurality of conductive portions disposed thereon, and an appropriate quantity of solder pastes coated onto each conductive portion; a chip module, situated at the top of the printed circuit board, and having a plurality of contact portions disposed at the bottom of the chip module and corresponding to the conductive portions respectively; wherein at least one support portion is formed between the chip module and the printed circuit board, and an end of the support portion is coupled to the printed circuit board and another end of the support portion is coupled to an area of the contact portions on the chip module, such that when the chip module and the printed circuit board are deformed in a high-temperature process, each contact portion is still in contact with the solder paste on the corresponding the conductive portion.

Compared with the prior art, the soldering of the electronic device of the present invention takes place in the reflow furnace when the chip module is soldered onto the printed circuit board, so that the rising temperature in the furnace will warp the printed circuit board upward at the middle and downward at the periphery, and the support portion will keep a specific distance between the two, such that the melted solder paste will not expand and disperse excessively towards the periphery or cause adjacent solder pastes to be contacted with each other, so as to prevent a short circuit.

These and other aspects of the present invention will become apparent from the following description of the preferred embodiment taken in conjunction with the following drawings and their captions, although variations and modifications therein may be affected without departing from the spirit and scope of the novel concepts of the disclosure.

### BRIEF DESCRIPTION OF THE DRAWINGS

The drawings described below are for illustration purposes only. The drawings are not intended to limit the scope of the present teachings in any way.

FIG. 1 is an exploded view of a conventional electronic device;

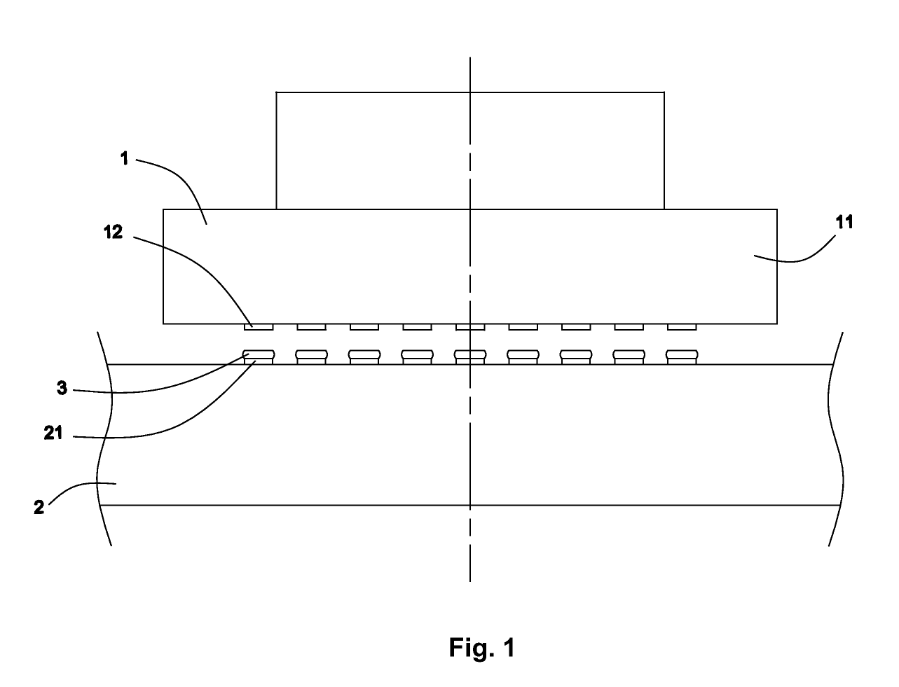

FIG. 2 is an exploded view of an electronic device in accordance with a first preferred embodiment of the present invention;

FIG. 3 is a perspective view of an electronic device in accordance with a first preferred embodiment of the present invention;

FIG. 4 is an exploded view of an electronic device in accordance with a second preferred embodiment of the present invention;

FIG. 5 is a perspective view of an electronic device in accordance with a second preferred embodiment of the present invention;

FIG. 6 is an exploded view of an electronic device in accordance with a third preferred embodiment of the present invention; and

FIG. 7 is a perspective view of an electronic device in accordance with a third preferred embodiment of the present invention.

### DETAILED DESCRIPTION OF THE PREFERRED EMBODIMENTS

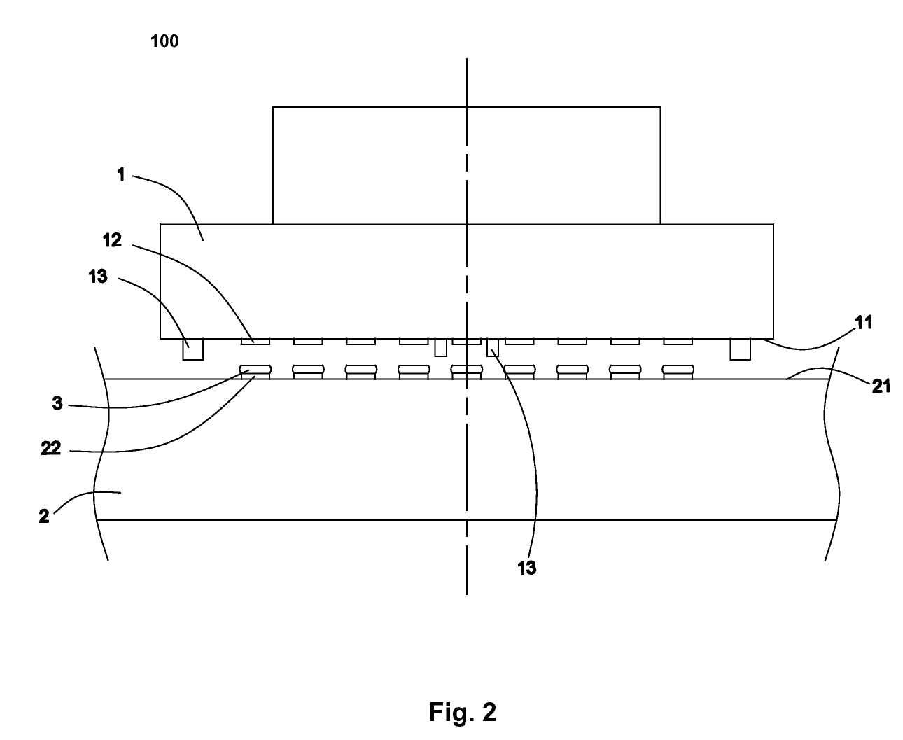

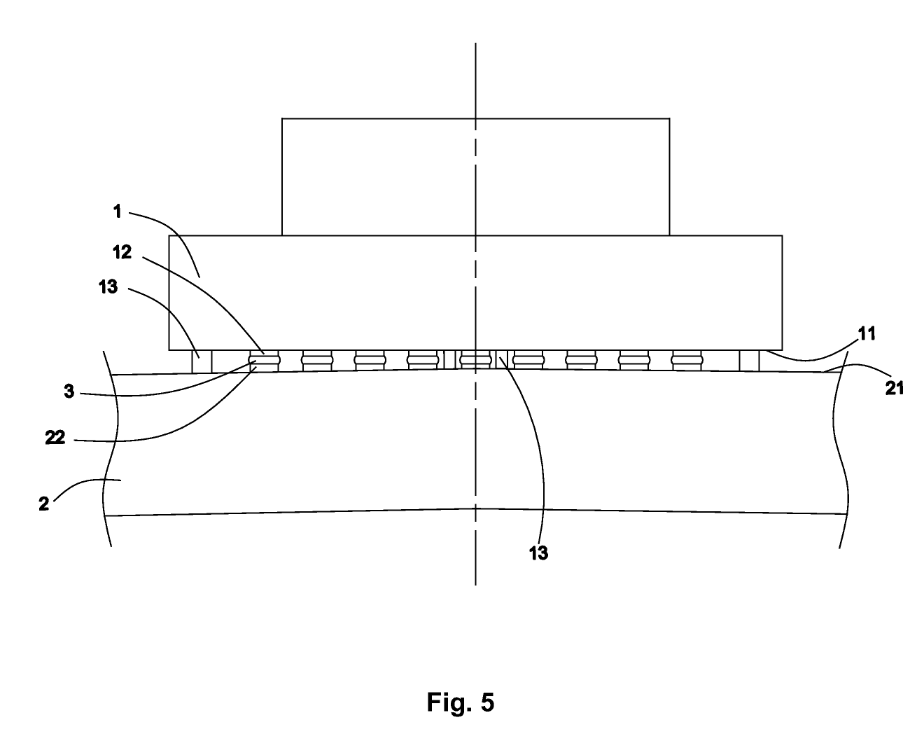

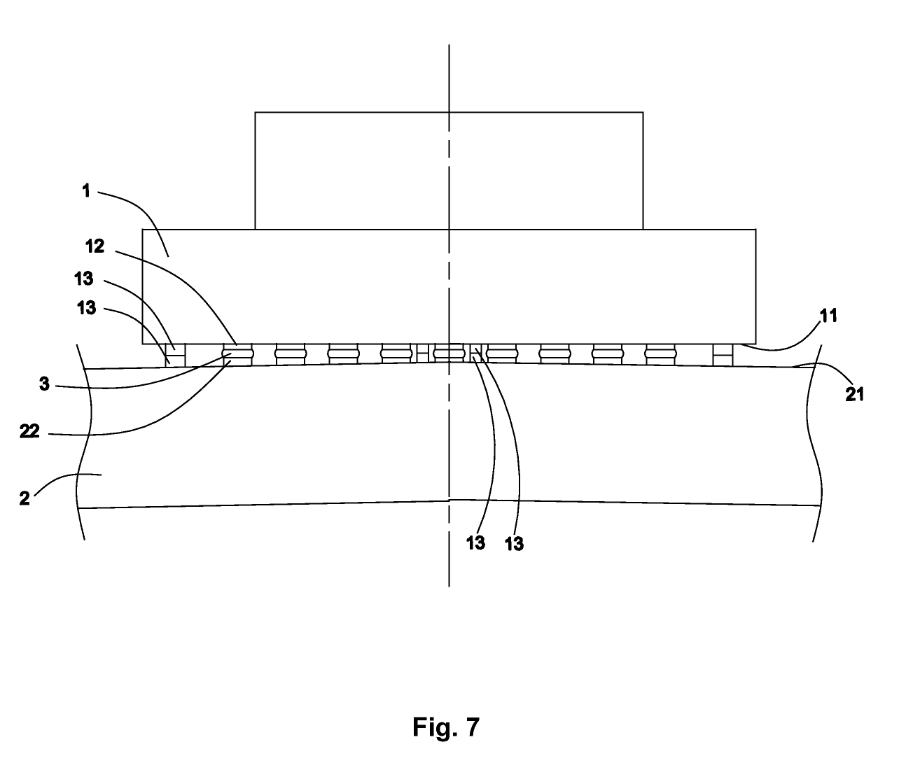

The present invention is more particularly described in the following examples that are intended as illustrative only since numerous modifications and variations therein will be apparent to those skilled in the art. Various embodiments of the invention are now described in detail. Referring to the drawings, FIGS. 2-7, like numbers, if any, indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

### DEFINITIONS

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

Unless otherwise defined, all technical and scientific terms used herein have the same meaning as commonly understood by one of ordinary skill in the art to which this invention pertains. In the case of conflict, the present document, including definitions will control.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, “plurality” means two or more.

As used herein, the terms “comprising,” “including,” “carrying,” “having,” “containing,” “involving,” and the like are to be understood to be open-ended, i.e., to mean including but not limited to.

With reference to FIG. 2 for an electronic device 100 in accordance with a first preferred embodiment of the present invention, the electronic device 100 has a chip module 1, a printed circuit board 2 disposed under the chip module 1, and a solder paste 3 coated onto the printed circuit board 2.

In FIG. 2, the chip module 1 has a bottom 11, a plurality of contact portions 12 disposed downwardly from the bottom 11, and a plurality of support portions 13, wherein each support portion 13 is situated at the bottom 11 of the chip module 1 and in an area having the contact portions 12 or without the contact portions 12. The printed circuit board 2 has a top 21, a plurality of conductive portions 22 disposed on the top 21 and corresponding to the contact portions 12 respectively, wherein each conductive portion 22 is coated with an appropriate quantity of solder pastes 3. The support portion 13 has a thickness not smaller than the total thickness of the conductive portion 22 and the contact portion 12 and not greater than the total thickness of the conductive portion 22, the contact portion 12 and the solder paste 3.

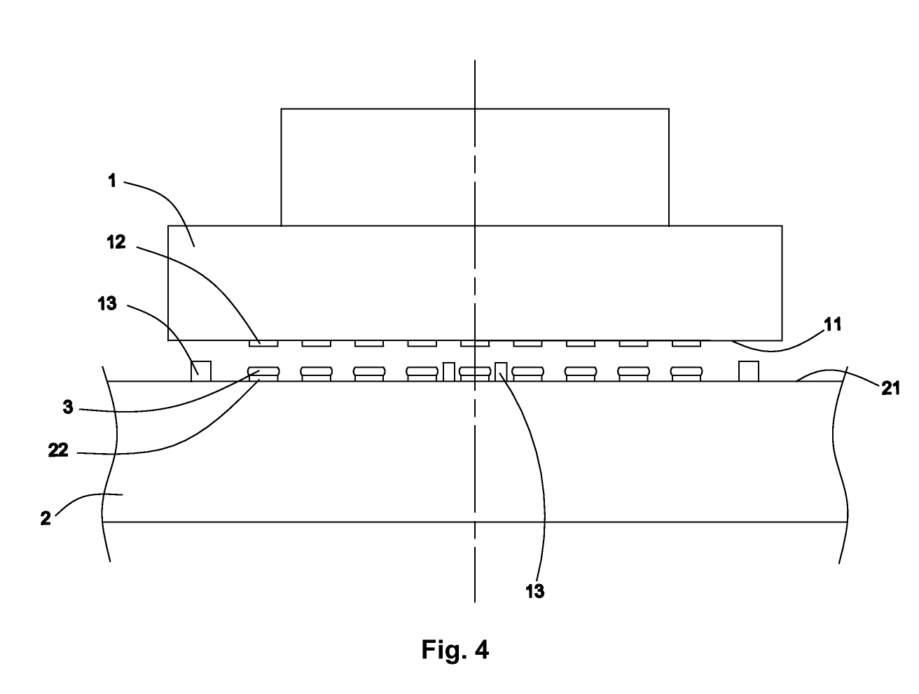

With reference to FIG. 4 for an electronic device in accordance with a second preferred embodiment of the present invention, the difference between the second preferred embodiment and the first preferred embodiment in one aspect resides on that the support portion 13 is situated at the top 21 of the printed circuit board 2 and in an area having the conductive portions 22 instead of the area without the conductive portions 22.

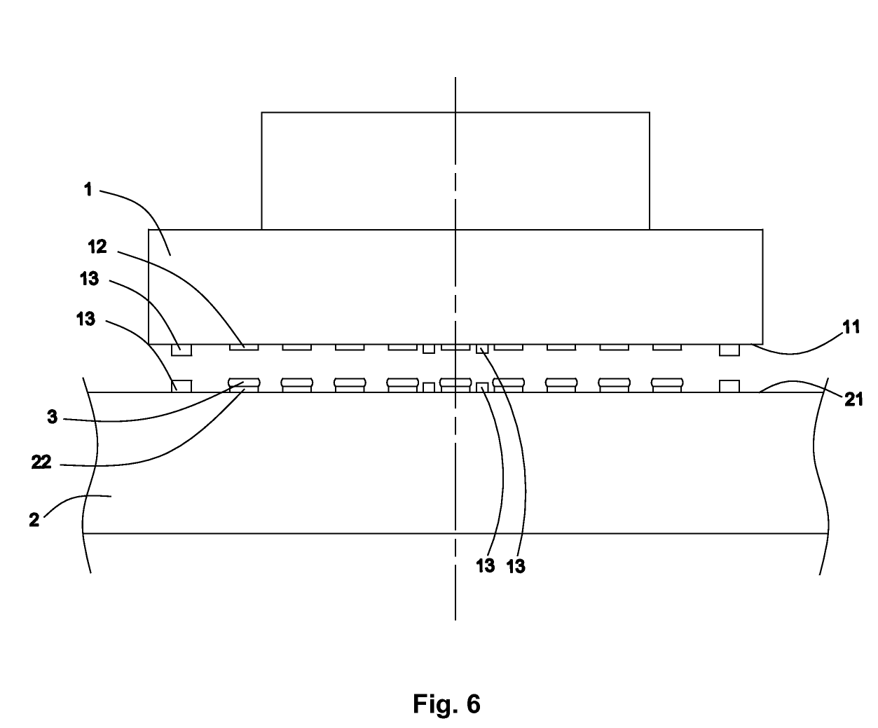

With reference to FIG. 6 for an electronic device in accordance with a third preferred embodiment of the present invention, the difference between the third preferred embodiment and the first preferred embodiment in one aspect resides on that the bottom 11 of the chip module 1 in an area having the contact portions 12 and the top 21 of the printed circuit board 2 in an area having the conductive portions 22 of the third preferred embodiment include the support portions 13 respectively, and the bottom 11 of the chip module 1 in an area without the contact portions 12 and the top 21 of the printed circuit board 2 in an area without the conductive portions 22 include symmetric support portions 13, and the support portion 13 on the chip module 1 and the support portion 13 on the printed circuit board 2 correspond to each other vertically.

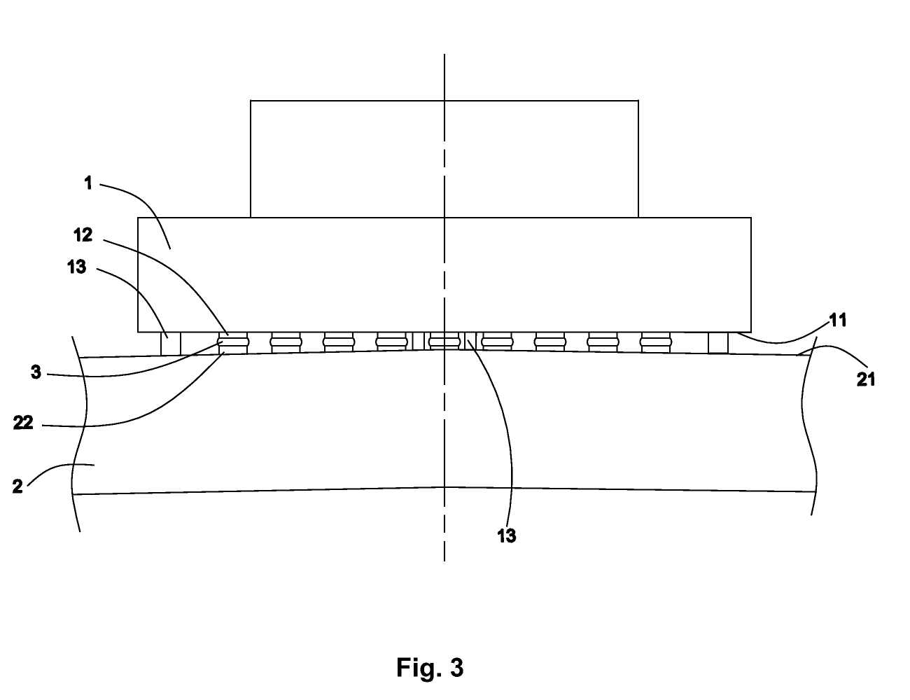

With reference to FIGS. 3, 5 and 7, respectively, the electronic device is soldered in a reflow furnace (not shown in the figure) to electrically connect the chip module 1 and the printed circuit board 2.

Firstly, each conductive portion 22 on the printed circuit board 2 is coated with an appropriate quantity of solder pastes 3, and then the chip module 1 is pressed downward to the printed circuit board 2, and the contact portions 12 are in contact with the solder pastes 3, and then the chip module 1 and the printed circuit board 2a are put and soldered in the reflow furnace, and the solder pastes 3 are melted by the high-temperature soldering process. In the first preferred embodiment, the support portion 13 on the chip module 1 pushes the top 21 of the printed circuit board 2. In the second preferred embodiment, the bottom 11 of the chip module 1 presses on the support portion 13 of the printed circuit board 2. In the third preferred embodiment, the support portion 13 on the chip module 1 and the support portion 13 on the printed circuit board 2 correspond to each other vertically to maintain a specific distance between the chip module 1 and the printed circuit board 2, such that if the chip module 1 and the printed circuit board 2 are deformed in the high-temperature process, each contact portion 12 is still in contact with the solder paste 3 on the corresponding conductive portion 22 to prevent an overflow of the solder paste 3 caused by pressing the chip module 1, so as to assure a good soldering effect and a normal electric connection between the chip module 1 and the printed circuit board 2.

In summation of the description above, the electronic device(s) of the present invention has the following advantages:

1. When the chip module is soldered onto the printed circuit board, the soldering takes place in the reflow furnace, such that the rising temperature will warp the printed circuit board upward at the middle and downward at the periphery, and the support portion maintains a specific distance between the two, and the melted solder paste will not expand and disperse excessively towards the periphery to avoid adjacent solder pastes from being in contact with each other, so as to prevent short circuits.

2. Since the support portion can control the distance between the chip module and the printed circuit board, empty soldering or open soldering can be avoided to assure a good electric connection between the chip module and the printed circuit board.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electronic device, comprising:
a printed circuit board, having a plurality of conductive portions disposed thereon, and a layer of solder paste coated onto each conductive portion; and
a chip module, situated at the top of the printed circuit board, and having a plurality of contact portions disposed at the bottom of the chip module and each corresponding to one of the conductive portions, respectively,
wherein at least one support portion is formed between the chip module and the printed circuit board, and an end of the support portion is coupled to the printed circuit board and another end of the support portion is coupled to an area of the contact portions on the chip module, such that when the chip module and the printed circuit board are deformed in a high-temperature process, each contact portion is still in contact with the solder paste on the corresponding conductive portion.

2. The electronic device of claim 1, wherein the support portion is disposed at the bottom of the chip module and in an area having the contact portions.

3. The electronic device of claim 1, wherein the chip module includes at least two of the support portions symmetrically disposed at the bottom of the chip module and in an area without the contact portions.

4. The electronic device of claim 1, wherein the support portion is disposed at the top of the printed circuit board and in an area having the conductive portions.

5. The electronic device of claim 1, wherein the printed circuit board includes at least two of the support portions symmetrically disposed at the top of the printed circuit board and in an area without the conductive portions.

6. The electronic device of claim 1, further comprising at least one the support portion disposed at the bottom of the chip module and in an area having the contact portions and the top of the printed circuit board and in an area having the conductive portions respectively, and the support portions correspond to each other vertically.

7. The electronic device of claim 1, wherein the bottom of the chip module and the top of the printed circuit board include at least two of the support portions symmetrically and respectively disposed at areas without the contact portions, and the two support portions on the chip module correspond to the two support portions on the printed circuit board vertically and respectively.

8. The electronic device of claim 1, wherein the support portion has a thickness not smaller than the total thickness of the conductive portion and the contact portion.

9. The electronic device of claim 1, wherein the support portion has a thickness not greater than the total thickness of the conductive portion, the contact portion and the solder paste.

10. The electronic device of claim 1, wherein the chip module and the printed circuit board are soldered in a reflow furnace.

11. An electronic device, comprising:
a printed circuit board, having a plurality of conductive portions disposed thereon, and an appropriate quantity of solder paste coated onto each conductive portion;
a chip module, situated at the top of the printed circuit board, and having a plurality of contact portions disposed at the bottom of the chip module and corresponding to the conductive portions respectively;
wherein at least one support portion is formed between the chip module and the printed circuit board, and an end of the support portion is coupled to the printed circuit board and another end of the support portion is coupled to an area of the contact portions on the chip module, such that if the chip module and the printed circuit board are deformed in a high-temperature process, each contact portion is still in contact with the solder paste on the corresponding the conductive portion.

12. The electronic device of claim 11, wherein the support portion is disposed at bottom of the chip module and in an area having the contact portions.

13. The electronic device of claim 11, wherein the chip module includes at least two of the support portions symmetrically disposed at the bottom of the chip module and in an area without the contact portions.

14. The electronic device of claim 11, wherein the support portion is disposed at the top of the printed circuit board and in an area having the conductive portions.

15. The electronic device of claim 11, wherein the printed circuit board includes at least two of the support portions symmetrically disposed at the top of the printed circuit board and in an area without the conductive portions.

16. The electronic device of claim 11, further comprising at least one the support portion disposed at the bottom of the chip module and in an area having the contact portions and the top of the printed circuit board and in an area having the conductive portions respectively, and the support portions correspond to each other vertically.

17. The electronic device of claim 11, wherein the bottom of the chip module and the top of the printed circuit board include at least two of the support portions symmetrically and respectively disposed at areas without the contact portions, and the two support portions on the chip module correspond to the two support portions on the printed circuit board vertically and respectively.

18. The electronic device of claim 11, wherein the support portion has a thickness not smaller than the total thickness of the conductive portion and the contact portion.

19. The electronic device of claim 11, wherein the support portion has a thickness not greater than the total thickness of the conductive portion, the contact portion and the solder paste.

20. The electronic device of claim 11, wherein the chip module and the printed circuit board are soldered in a reflow furnace.
